(19) United States
(12) Patent Application Publication
(10) Pub. No.: US 2007/0246356 A1
(43) Pub. Date: Oct. 25, 2007

(54) SPUTTERING APPARATUS

(76) Inventor: Takumi TOKIMITSU, Utsunomiya-shi (JP)

Correspondence Address: MORGAN & FINNEGAN, L.L.P., 3 WORLD FINANCIAL CENTER, NEW YORK, NY, 10281-2101, US

(21) Appl. No.: 11/735,663

(22) Filed: Apr. 16, 2007

(30) Foreign Application Priority Data
Apr. 21, 2006 (JP) 2006-117850

(51) Int. Cl. C23C 14/00

(52) U.S. Cl. 204/298.02

(57) ABSTRACT

A sputtering apparatus is disclosed which enables highly accurate monitor control of a film thickness and allows enhanced flexibility in design. The apparatus includes a substrate placement area in which a substrate is placed, a particle emission area in which a target is placed and sputter particles from the target are emitted, and a sensor placement area in which a sensor is placed for measuring a thickness of a film formed on the substrate. The substrate placement area and the sensor placement area are provided in a positional relationship having symmetry with respect to a center line of the particle emission area.

### BACKGROUND OF THE INVENTION

The present invention relates to a sputtering apparatus for forming (depositing) a film on an object, and more particularly, to a sputtering apparatus which forms a film having a thickness controlled accurately by using a sensor for measuring a film thickness.

In sputtering apparatuses, a target serving as a material of a thin film and an object (hereinafter referred to as a substrate) on which the thin film should be deposited are placed in a film deposition chamber, and sputtering is performed through electrical discharge on a surface (sputtering surface) of the target to be sputtered, thereby producing the thin film made of metal or compound material on the surface (film deposition surface) of the substrate on which the film should be deposited.

Such sputtering apparatuses include opposed-type sputtering apparatuses in which a sputtering surface of a target is opposed to a film deposition surface of a substrate on which a film should be deposited, and off-axis type or opposed-target type sputtering apparatuses in which a sputtering surface of a target and a film deposition surface of a substrate are placed such that their centers are not aligned.

Since those sputtering apparatuses generally need to produce a thin film having a desired thickness, control of the thickness of the thin film is required. The method of controlling the film thickness in the sputtering apparatuses mainly include the following two types: a time control method for controlling the thickness of a film by changing the film deposition time; and a monitor control method of controlling the thickness of a film by using a sensor for measuring a film thickness provided in a sputtering apparatus.

In the monitor control method of the abovementioned film-thickness control methods, an optical sensor and a crystal oscillator sensor are principally used as the sensor for measuring the film thickness. When the optical sensor is used, a thin film is formed on the sensor to change optical characteristics of the sensor such as the reflectance, and the change is detected to measure the film thickness. When the crystal oscillator sensor is used, a thin film is formed on the sensor to change the resonance frequency of the crystal oscillator, and the change is detected to measure the film thickness.

In measuring the film thickness with such a film-thickness measuring sensor, a film is deposited on the sensor simultaneously with the deposition of a film on the substrate to allow estimation of the thickness of the film on the substrate. The film-thickness measuring sensor is typically installed on the side of the substrate as described in Japanese Patent Laid-Open No. 08(1996)-325725. In a sputtering apparatus disclosed in Japanese Patent Laid-Open No. 08(1996)-325725, a substrate holder has an opening formed therein, and a film-thickness measuring sensor is placed on the back of the substrate holder.

When the abovementioned monitor control method is used to control the film thickness, it is desirable that the film deposition rate on the sensor is not different from the film deposition rate on the substrate. This is because a significant difference in the film deposition rate reduces the accuracy in control of the film thickness.

It is contemplated that one of the causes of a difference between the film deposition rate on the sensor and the film deposition rate on the substrate is that particles for depositing a film are emitted by the target in asymmetric angular distribution for the sensor and the substrate. In other words, if the orientation of the substrate with respect to the target is different from the orientation of the sensor with respect to the target, a large difference occurs in the film deposition rate on the sensor and the film deposition rate on the substrate. When the sensor is installed as disclosed in Japanese Patent Laid-Open No. 08(1996)-325725, there is concern that control of film thickness is impaired due to such a difference in the film deposition rate.

When the film-thickness measuring sensor is placed near the substrate such as on the side or on the back of the substrate as disclosed in Japanese Patent Laid-Open No. 08(1996)-325725, flexibility in design within the film deposition chamber is limited. In the film deposition chamber, a shield container for protecting the film-thickness measuring sensor against electrical discharge and a shutter for reducing the number of replacements of the sensor are often placed, and a sensor unit including a plurality of sensors is often used. Those sensor-associated structures occupy a large volume of the film deposition chamber to limit the flexibility in design within the film deposition chamber. This results in limited flexibility in the area and method of placement of the substrate within the film deposition chamber.

### BRIEF SUMMARY OF THE INVENTION

The present invention provides a sputtering apparatus which enables highly accurate monitor control of a film thickness and allows enhanced flexibility in design.

According to an aspect, the present invention provides a sputtering apparatus including a substrate placement area in which a substrate is placed, a particle emission area in which a target is placed and sputter particles from the target are emitted, and a sensor placement area in which a sensor is placed for measuring a thickness of a film formed on the substrate. The substrate placement area and the sensor placement area are provided in the positional relationship having symmetry with respect to a center line of the particle emission area.

According to another aspect, the present invention provides a sputtering apparatus, including a substrate placement area in which a substrate is placed, a particle emission area in which a target is placed and sputter particles from the target are emitted, and a sensor placement area in which a sensor is placed for measuring a thickness of a film formed on the substrate. The substrate placement area and the sensor placement area are provided on the opposite sides with respect to the particle emission area.

Other objects and features of the present invention will be apparent from the following description of preferred embodiments with reference to the accompanying drawings.

### BRIEF DESCRIPTION OF THE DRAWINGS

FIG. 1 is a schematic diagram showing the structure of a sputtering apparatus which is Embodiment 1 of the present invention.

FIG. 2 shows the positional relationship between a particle emission area, a substrate placement area, and a sensor placement area in the sputtering apparatus of Embodiment 1.

FIG. 3 is a graph showing the result of the experiment on film-thickness control with the sputtering apparatus of Embodiment 1.

FIG. 4 is a graph showing the dependence of the film deposition rate on the distance between the particle emission area and the substrate in the sputtering apparatus of Embodiment 1.

FIG. 5 shows the positional relationship between a particle emission area, a substrate placement area, and a sensor placement area in a sputtering apparatus of Embodiment 2.

FIG. 6 shows the positional relationship between a particle emission area, a substrate placement area, and a sensor placement area in a sputtering apparatus of Embodiment 3.

FIG. 7 shows the positional relationship between a particle emission area, a substrate placement area, and a sensor placement area in a sputtering apparatus of Embodiment 4.

FIG. 8 is a flow chart showing the procedure of film deposition in the sputtering apparatuses of Embodiments 1 to 4.

FIGS. 9A to 9E show examples of a target usable in the sputtering apparatuses of Embodiments 1, 3, and 4.

FIGS. 10A to 10D show examples of a target usable in the sputtering apparatus of Embodiment 2.

FIGS. 11A to 11C show examples of the target usable in the sputtering apparatuses of Embodiment 2.

FIG. 12 shows an example of a target usable in the sputtering apparatus of Embodiment 4.

FIG. 13 shows the structure of a sputtering apparatus which is a modification of Embodiment 2.

### DETAILED DESCRIPTION OF THE PREFERRED EMBODIMENTS

Preferred embodiments of the present invention will hereinafter be described with reference to the drawings.

### Embodiment 1

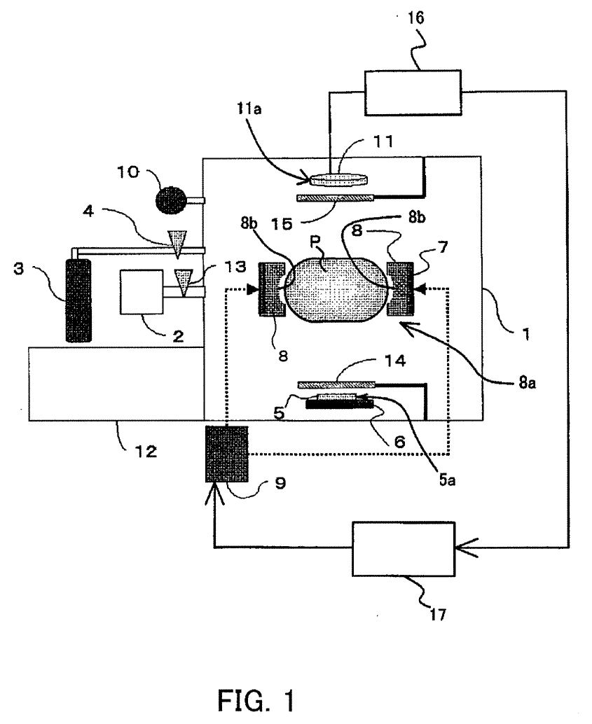

FIG. 1 shows the structure of a sputtering apparatus which is Embodiment 1 of the present invention. The sputtering apparatus of Embodiment 1 includes a film deposition chamber (vacuum chamber) 1 in which a film is deposited, a vacuum pump 2 which performs exhaust from the film deposition chamber 1, and a gas cylinder 3 which introduces, into the film deposition chamber 1, a gas for producing plasma discharge within the film deposition chamber 1. Gasses for use in the sputtering apparatus include an inert gas such as Ar (argon) and He (helium), and a mixture such as a mixture of an inert gas and O₂ (oxygen) or N₂ (nitrogen).

An exhaust valve 13 is provided for controlling the volume of exhaust between the film deposition chamber 1 and the vacuum pump 2. A gas introducing valve 4 is provided for controlling the supply of the gas between the film deposition chamber 1 and the gas cylinder 3.

The sputtering apparatus also includes a load lock chamber 12 for carrying a substrate 5, on which a film should be deposited, into and out of the film deposition chamber 1 while a high vacuum is maintained in the film deposition chamber 1. The sputtering apparatus 1 also includes a vacuum gauge 10 for measuring the pressure (degree of vacuum) in the film deposition chamber 1.

A substrate holder 6 for holding the substrate 5 is provided in the film deposition chamber 1. A spatial area in which the substrate 5 is placed by being held by the substrate holder 6 will hereinafter be referred to as a substrate placement area 5a. The substrate 5 is realized, for example, by an optical element such as a lens on which an optical film is formed such as an antireflective film and a semi-reflective film, a glass plate on which a transparent conductive film (ITO, ZnO), a barrier film (SiOx, SiON) or the like is formed, a resin film, or the like.

Two sets of discharge electrodes 7 and targets 8 made of aluminum or another material for film deposition are placed above the substrate placement area 5a in the film deposition chamber 1. Each set of the discharge electrodes 7 and the targets 8 is held by a target holder, not shown, in the film deposition chamber 1. A spatial area in which the two targets 8 are placed by being held by the target holders and thus are placed and emit sputter particles will hereinafter be referred to as a particle emission area 8a.

The sputtering apparatus of Embodiment 1 is of the off-axis or opposed-target type in which the two planar targets 8 are placed such that their sputtering surfaces 8b are opposite to each other. The sputtering surfaces 8b serve as surfaces from which the sputter particles are emitted. The discharge electrodes 7 are connected to a power 9 for applying an electric field (direct-current electric field, pulse electric field, high-frequency electric field or the like) to the targets 8 to produce plasma P between the targets 8.

A film-thickness measuring sensor (hereinafter referred to simply as a sensor) 11 serving as a sensing element for measuring the thickness of a produced thin film (film thickness) is provided above the particle emission area 8a in the film deposition chamber 1. A crystal oscillator is used as the sensor 11 of Embodiment 1. The sensor 11 is held by a sensor holder, not shown, in the film deposition chamber 1. A spatial area in which the sensor 11 is placed by being held by the sensor holder and thus is placed will hereinafter be referred to as a sensor placement area 11a.

A measuring device 16 measures (monitors) the film thickness by detecting a change in the resonance frequency of the crystal oscillator resulting from the formation of a thin film on the sensor (crystal oscillator) 11.

An optical sensor may be used for measuring the film thickness. In such a case, the sensing element (sensor 11) is realized by an element which shows a change in optical characteristics such as the reflectance depending on the film thickness.

A control unit 17 controls the operation of the power 9, the gas introducing valve 4 and the like based on the results of film-thickness measurement by the sensor 11 and the measuring device 16 such that the film formed on the substrate 5 has a desired thickness. In other words, the control unit 17 performs the control on the assumption that the film thickness on the sensor 11 is equivalent to the film thickness on the substrate 5.

A substrate shutter 14 is provided for controlling when to start and stop the film deposition between the targets 8 and the substrate 5. A sensor shutter 15 is provided for controlling when to start and stop film-thickness monitoring between the targets 8 and the sensor 11. The operations of the shutters 14 and 15 are controlled by the control circuit 17.

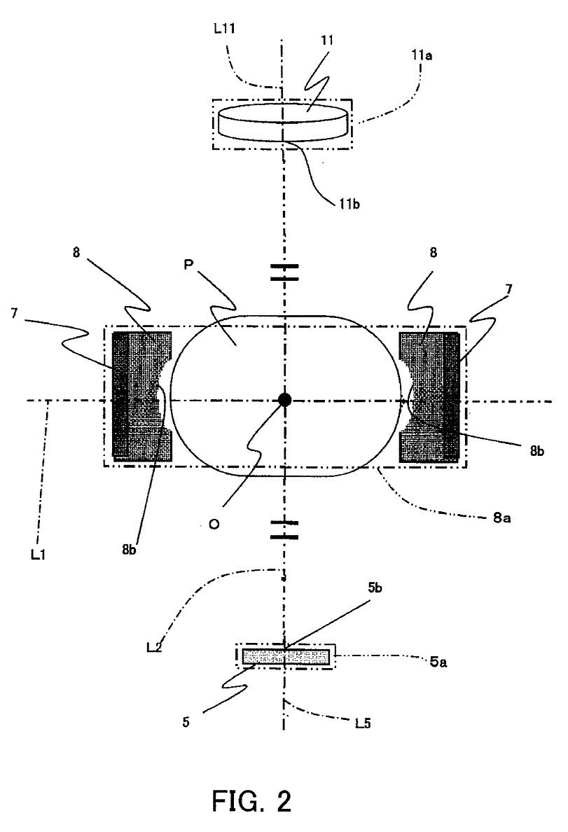

FIG. 2 shows the positional relationship between the substrate placement area 5a, the particle emission area 8a, and the sensor placement area 11a shown in FIG. 1. FIG. 2 shows the three areas 5a, 8a, and 11a with chain double dashed lines. To facilitate understanding of the positional relationship between the three areas 5a, 8a, and 11a, FIG. 2 shows the three areas 5a, 8a, and 11a on which the substrate 5, the targets 8, and the sensor 11 are placed, respectively. This represents the state in which the sputtering apparatus is used.

As described above, in the sputtering apparatus of Embodiment 1, the two planar targets 8 are placed on the left and right in the particle emission area 8a such that their sputtering surfaces 8b are opposite to each other. In FIG. 2, L1 shows the center line of the particle emission area 8a in the vertical direction, while L2 shows the center line of the particle emission area 8a in the horizontal direction.

The center line L1 intersects the center line L2 at a point O. The point O is the center of the particle emission area 8a. The center line L2 passes through centers 5b and 11b of the substrate placement area 5a and the sensor placement area 11a, respectively.

The sputtering apparatus of Embodiment 1 is of the off-axis or opposed-target type as described above. In this case, the particle emission area 8a does not simply mean the two areas in which the targets 8 are placed on the left and right in the horizontal direction. The particle emission area 8a refers to the area in which the targets 8 are placed and the particles (sputter particles) may be emitted from the targets 8 toward the substrate 5 and the sensor 11 while the plasma P is formed between the targets 8.

When the sputtering surfaces 8b of the targets 8 have shapes which are rotationally symmetric or linearly symmetric in the vertical direction or horizontal direction (direction perpendicular to the sheet of FIG. 2), the center line L1 of the particle emission area 8a in the vertical direction is identical to the axis of rotational symmetry or the axis of linear symmetry. In other words, the center line L1 passes through the centers of the shapes of the sputtering surfaces 8b of the targets 8.

The center line L1 of the particle emission area 8a is not limited to the straight line which passes through the centers of the shapes of the sputtering surfaces 8b. For example, when the sputtering surfaces 8b have asymmetric shapes (so-called irregular shapes), the center line L1 may be defined as the straight line which connects between the barycenters of the sputtering surfaces 8b.

Regardless of the shapes of the sputtering surfaces 8b, the center line L1 may be defined as the straight line which passes through the points of the sputtering surfaces 8b at which sputtering actually causes the largest change in shape during film deposition (the largest consumption amount of the target). Such a point can be predicted in designing the apparatus. If a single target has a plurality of positions at which sputtering causes the largest change in shape, the center of those positions may be used as the center of the target.

On the other hand, the center line L2 corresponds to the straight line which is orthogonal to the center line L1 defined as described above and is at equal distances from the sputtering surfaces 8b of the targets 8.

The surfaces (film deposition surfaces) of the substrate 5 and the sensor 11 used in Embodiment 1 on which films should be deposited have shapes which are rotationally symmetric, linearly symmetric, or irregular. The centers 5b and 11b of the substrate placement area Sa and the sensor placement area 11a, respectively, are identical to the positions of the centers or the barycenters of the shapes of the film deposition surfaces in the substrate 5 and the sensor 11 or the positions of the references in controlling film deposition on the substrate 5 and the sensor 11. Center lines L5 and L11 passing through the centers 5b and 11b of the substrate placement area 5a (substrate 5) and the sensor placement area 11a (sensor 11), respectively, are identical to the central line L1 in Embodiment 1. When the angle of the center line L5 with respect to the L1 is different from angle of the center line L11 with respect to the center line L1 by ±10%_or smaller, the both angles are considered to be equal.

In Embodiment 1, although not shown, each of the film deposition surfaces of the substrate 5 and the sensor 11 is made of a spherical surface, and the center lines L5 and L11 correspond to the normals to the film deposition surfaces at their centers. Thus, the center lines L5 and L11 are also the center lines of the substrate 5 and the sensor 11 placed in the substrate placement area 5a and the sensor placement area 11a, respectively.

In Embodiment 1, the sensor placement area 11a and the substrate placement area 5a are provided above and below the particle emission area 8a, that is, on the opposite sides thereof. The distance from the center O of the particle emission area 8a to the center 11b of the sensor placement area 11a along the center line L2 is equal to the distance from the center O to the center 5b of the substrate placement area 5a. When the distance from the center O of the particle emission area 8a to the center 11b of the sensor placement area 11a is different from the distance from the center O to the center 5b of the substrate placement area 5a by ±10% or smaller, both of the distances are considered to be equal.

In the abovementioned positional relationship, the substrate placement area 5a (that is, the substrate 5) and the sensor placement area 11a (that is, the sensor 11) have symmetry with respect to the center line L1 of the particle emission area 8a. In other words, the substrate placement area 5a and the sensor placement area 11a are placed in the conjugate positional relationship with respect to the particle emission area 8a from the viewpoint of film deposition conditions.

Satisfying such a positional relationship can provide the equivalent film deposition conditions for the substrate 5 and the sensor 11. As a result, the film deposition rate on the substrate 5 can be equivalent to the film deposition rate on the sensor 11. Thus, as described above, it can be assumed that the film-thickness measurement result by the sensor 11 is equivalent to the film thickness on the substrate 5, so that the control unit 17 can accurately control the thickness of the film formed on the substrate 5 based on a target value.

The assumption that the film deposition rates, that is, the film thicknesses are equivalent in this case means that the difference between the film deposition rate (film thickness) on the sensor 11 and the film deposition rate (film thickness) on the substrate 5 is ±20% or smaller, more desirably, ±10% or smaller.

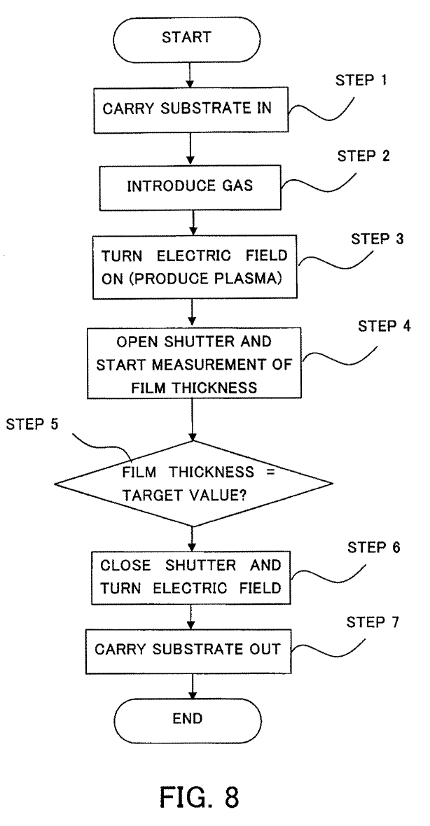

Next, the procedure of depositing a film with the sputtering apparatus of Embodiment 1 will be described with reference to FIG. 8. The film deposition procedure in FIG. 8 applies to Embodiments 2 to 4, later described.

First, the sensor 11 is placed in advance in the sensor placement area 11a within the film deposition chamber 1. Then, the substrate 5 is carried into the film deposition chamber 1 via the load lock chamber 12 and is held by the substrate holder 6 (step 1). In this manner, the substrate 5 is placed in the substrate placement area 5a.

Next, a controlled supply amount of gas for electrical discharge is introduced into the film deposition chamber 1 by the gas introducing valve 4 (step 2).

An electrical filed is applied to the discharge electrodes 7 to produce plasma discharge. The targets 8 are sputtered to emit the sputter particles from the particle emission area 8a (step 3). For the gas used in the apparatus, an Ar gas is introduced when metal aluminum is deposited, while a mixture of O₂ and Ar is introduced when alumina is deposited.

While the plasma discharge is produced, the substrate shutter 14 is opened (step 4). This causes formation of a thin film to be started on the substrate 5. Simultaneously with or slightly before the opening of the substrate shutter 14, the sensor shutter 15 is opened. This causes formation of a thin film to be started on the sensor 11 to allow monitoring of a change in the thickness of the film over time. When the sensor shutter 15 can be opened before the opening of the substrate shutter 14, the film deposition can be started after it is made sure that the film deposition rate is stabilized. The change in the film thickness on the sensor 11 can be monitored over time in this manner, so that it is possible to determine when to stop the film deposition in accordance with a desired film thickness by using the relationship between the film deposition rate on the sensor 11 and the film deposition rate on the substrate 5.

In conventional sputtering apparatuses, the sensor and the substrate are placed in a positional relationship having no symmetry with respect to the center line of the particle emission area (non-conjugate positional relationship from the viewpoint of film deposition conditions).

For this reason, the film deposition rate on the sensor is significantly different from the film deposition rate on the substrate, so that it is necessary to measure the relationship between these film deposition rates in advance or to re-measure the relationship after each film deposition. In addition, when the angular distribution of sputter particles emitted from the target is changed due to the state of the target or the electrical discharge, the relationship between the film deposition rate on the sensor and the film deposition rate on the substrate cannot be maintained, thereby making it difficult to realize highly accurate control of the film thickness.

In the sputtering apparatus of Embodiment 1, however, the sensor 11 and the substrate 5 are placed in the positional relationship having symmetry with respect to the center line L1 of the particle emission area 8a (conjugate positional relationship from viewpoint of film deposition conditions). The film deposition rate on the sensor 11 can be considered to be equivalent to the film deposition rate on the substrate without any problems. This essentially obviates the need to measure the relationship between the film deposition rates in advance.

In actual use of the sputtering apparatus, the relationship between the film deposition rates often needs to be examined by way of precaution. However, in this case, the sputtering apparatus of Embodiment 1 has an advantage that the frequency of measurement of the relationship between the film deposition rates is reduced or that the accuracy of the determined relationship is increased.

Even when the angular distribution of the sputter particles emitted form the targets 8 (particle emission area 8a) is changed, it is possible to maintain the relationship in which the film deposition rate on the sensor 11 is considered to be equivalent to the film deposition rate on the substrate 5. Thus, the highly accurate control of the film thickness can be achieved.

When the film thickness measured by the sensor 11 reaches a target value (step 5), the substrate shutter 14 is closed (step 6). The application of the electric field to the discharge electrodes 7 is stopped. In this manner, the thin film having the desired thickness can be provided on the substrate 5. Finally, the substrate having the film deposited thereon is taken out of the film deposition chamber 1 via the load lock chamber 12 (step 7) to end the deposition process. When deposition is subsequently performed on a next substrate 5, the sensor 11 is replaced, or a sensor unit including a plurality of sensors 11 is moved to place an unused sensor 11 in the sensor placement area 11a.

As described above, in Embodiment 1, the substrate placement area 5a and the sensor placement area 11a are provided on the opposite sides of the particle emission area 8a in the opposed-target or off-axis sputtering apparatus. In other words, the substrate placement area 5a and the sensor placement area 11a are placed in the two areas divided by the particle emission area 8a. This can dramatically improve the flexibility in design within the film deposition chamber 1 as compared with the case where the sensor is placed in the substrate placement area or the equivalent area when viewed from the particle emission area such as on the side or on the back of the substrate.

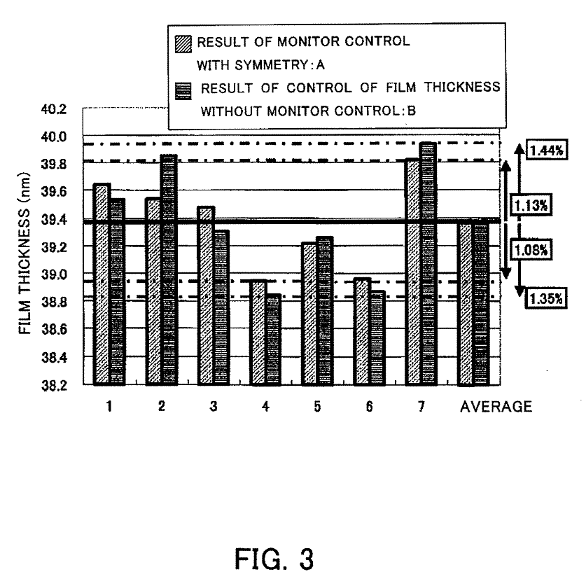

FIG. 3 shows the result of the experiment on monitor control of the film thickness in the sputtering apparatus of Embodiment 1. In FIG. 3, bars A represent the result of monitor control of the film thickness (monitor control with symmetry) in the sputtering apparatus of Embodiment 1 including the sensor 11 and the substrate 5 placed in the positional relationship having symmetry with respect to the center line L1 of the particle emission area 8a.

In the experiment, a quartz plate was used as the substrate and a target value of the film thickness was set to 39.35 nm. After the substrate was taken from the film deposition chamber, the film thickness on the substrate was measured by a spectrometer as the film thickness after the deposition. The monitor control with symmetry was performed seven times in the experiment.

In FIG. 3, bars B represent the film thicknesses (calculated values) when the monitor control with symmetry was not performed and film deposition was performed for a controlled time period regarded as being necessary for providing the same target film thickness as that in the monitor control with symmetry. In the monitor control, the film deposition time varies depending on the film thickness measured by the sensor. The film thickness in the time control is determined with the following expression:

(converted film thickness when film deposition time is controlled)=(film thickness in monitor control)×(average film deposition time in monitor control)/(film deposition time in monitor control)

The error of the film thickness in the time control determined as described above relative to the target value ranges from 1.44% to −1.35%.

In contrast, the error of the film thickness when the monitor control with symmetry was performed relative to the target value ranges from +1.13% to −1.08%, which means improved accuracy in film-thickness control as compared with the time control.

In the monitor control in which the substrate placement area and the sensor placement area are not symmetric with respect to the center line of the particle emission area as described in Japanese Patent Laid-Open No. 08(1996)-325725 (hereinafter referred to as asymmetric monitor control), it is contemplated that the accuracy in film-thickness control is improved as compared with the time control. In the asymmetric monitor control, however, the angular distribution of particles for film deposition emitted from the target is asymmetric for the sensor and the substrate, and it is easily conceivable that a nonnegligible difference occurs in the film deposition rate on the sensor and the film deposition rate on the substrate. Thus, it is contemplated that the accuracy of the film deposition control in the monitor control with symmetry is also improved as compared with the accuracy of the film deposition control in the asymmetric monitor control.

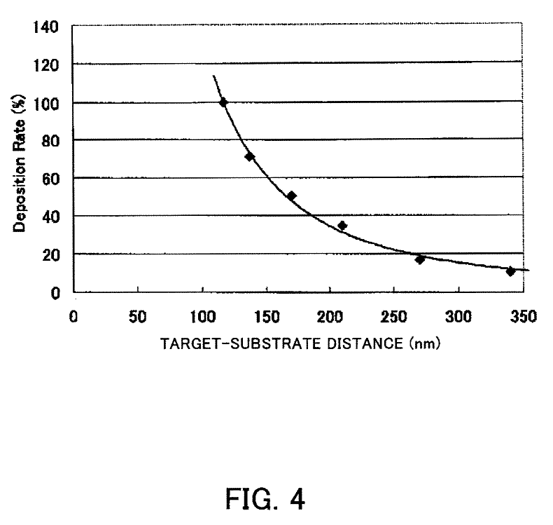

FIG. 4 shows the result of the experiment on dependence of the substrate film deposition rate on the distance in the sputtering apparatus of Embodiment 1. The dependence of the substrate film deposition rate on the distance refers to dependence on the distance (hereinafter referred to as T-S1 distance) from the center O of the particle emission area 8a to the center 5b of the substrate 5 (substrate placement area 5a).

The substrate film deposition rate is plotted assuming that the film deposition rate is equal to 100 when the T-S1 distance is 117.5 mm. While the optimal T-S1 distance is determined by the thickness of a film to be formed, the area of the substrate and the like, it is set to a range from approximately 100 to 350 mm in Embodiment 1. The substrate film deposition rate is proportional to the reciprocal of the square of the T-S1 distance.

The dependence of the film deposition rate on the substrate 5 on the distance is similar to that in the film deposition on the sensor 11 in the sputtering apparatus of Embodiment 1. For the sensor 11, the distance from the center O of the particle emission area 8a to the center 11b of the sensor 11 (sensor placement area 11a) is set to a T-S2 distance. In this case, to reduce a difference of the sensor film deposition rate (film thickness on the sensor) from the substrate film deposition rate (film thickness on the substrate) to ±20% or less, a difference of the T-S2 distance from the T-S1 distance needs to be set to ±10% or less.

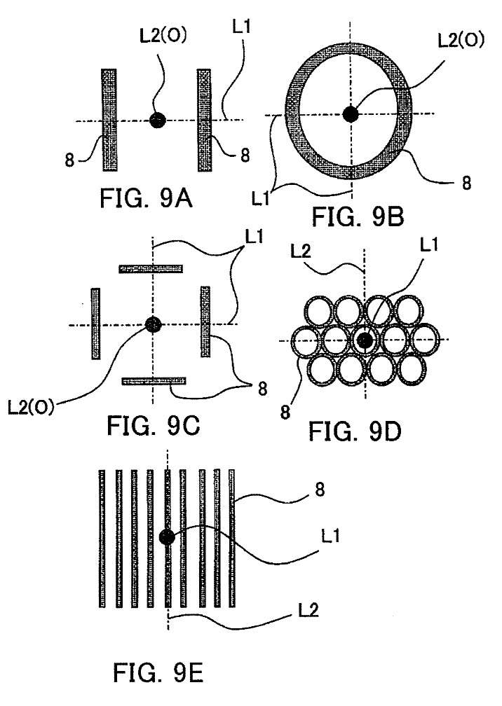

In the sputtering apparatus of Embodiment 1, it is possible to use targets 8 having various shapes and arrangements as shown in FIGS. 9A to 9E. FIGS. 9A to 9C show the shapes of targets 8 in the horizontal direction when viewed from the center line L2. FIGS. 9D and 9E show the shapes of targets 8 in the vertical direction when viewed from the center line L1.

FIG. 9A shows two targets 8 opposite to each other as described in Embodiment 1. FIG. 9B shows target 8 in a ring shape. FIG. 9C shows two sets of targets 8 (four targets in total) in which each set includes two targets 8 opposite to each other.

FIG. 9D shows a target 8 which includes a plurality of target cells in a cylindrical (or ring) shape. FIG. 9E shows a target 8 which includes a plurality of target cells as parallel plates (or parallel bars). The targets shown in FIGS. 9D and 9E are placed opposite to each other as shown in FIGS. 9A and 9C.

When any targets of the shapes and arrangements as shown are used, the center O and the center lines L1, L2 of the particle emission area can be specified in accordance with the abovementioned definitions.

### Embodiment 2

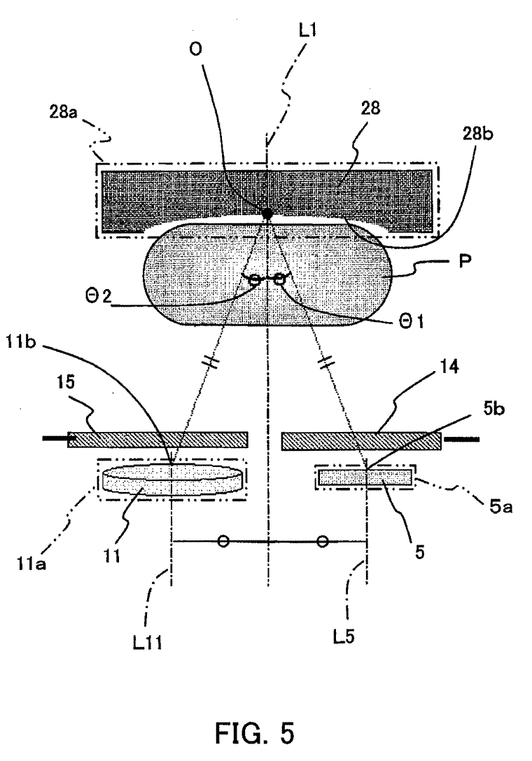

FIG. 5 shows the positional relationship between a particle emission area 28a, a substrate placement area 5a, and a sensor placement area 11a in the structure of a sputtering apparatus which is Embodiment 2 of the present invention. The three areas 5a, 28a, and 11a are shown by chain double dashed lines. FIG. 5 shows a substrate 5, a target 28, and a sensor 11 placed in the three areas 5a, 28a, and 11a, respectively. In Embodiment 2, components identical to those in Embodiment 1 are designated with the same reference numerals as those in Embodiment 1. This applies to Embodiments 3 and 4, later described.

The sputtering apparatus of Embodiment 2 is of a parallel-plate type (opposed type) in which the target 28 in a planar shape is placed in the particle emission area 28a such that a sputtering surface 28b faces the substrate 5 and the sensor 11. In FIG. 5, O represents the center of the particle emission area 28a, and L1 represents the center line of the particle emission area 28a passing through the center O. In Embodiment 2, the center O of the particle emission area 28a is identical to the center of the sputtering surface 28b of the target 28. The center line L1 of the particle emission area 28a corresponds to the straight line orthogonal to the sputtering surface 28b.

The center of the sputtering surface 28b that is the center O of the particle emission area 28a can be defined as the position through which the axis of symmetry passes when the sputtering surface 28b has a rotationally symmetric shape or a linearly symmetric shape, or as the position through which the barycenter passes when it has an asymmetric shape. As described in Embodiment 1, the center of the sputtering surface 28b may be set at the position of the sputtering surface 28b at which sputtering causes the largest change in shape (the largest consumption amount of the target). The centers and center lines of the substrate placement area 5a, the substrate 5, the sensor placement area 11a, and the sensor 11 are defined in the same manner as that in Embodiment 1.

In the sputtering apparatus of Embodiment 2, similarly to Embodiment 1, the substrate placement area 5a (that is, the substrate 5) and the sensor placement area 11a (that is, the sensor 11) are placed in the positional relationship having symmetry with respect to the center line L1 of the particle emission area 28a. In other words, they are in the conjugate positional relationship from the viewpoint of film deposition conditions.

More specifically, the distance from the center O of the particle emission area 28a to the center 5b of the substrate placement area 5a (substrate 5) is equal to the distance from the center O of the particle emission area 28a to the center 11b of the sensor placement area 11a (sensor 11). The straight line connecting the center O of the particle emission area 28a to the center 5b of the substrate placement area 5a is referred to as a first straight line, while the straight line connecting the center O of the particle emission area 28a to the center 11b of the sensor placement area 11a is referred to as a second straight line. In this case, an angle θ1 between the first straight line and the center line L1 is equal to an angle θ2 between the second straight line and the center line L2.

When the distance from the center O of the particle emission area 28a to the center 11b of the sensor placement area 11a is different from the distance from the center O of the particle emission area 28a to the center 5b of the substrate placement area 5a by ±10% or less, the distances are considered to be equal. When the angle θ2 is different from the angle θ1 by ±10% or less, the angles are considered to be equal.

Center lines L5 and L11 passing through the centers 5b and 11b of the substrate placement area 5a (substrate 5) and the sensor placement area 11a (sensor 11), respectively, are in parallel with the center line L1. In this case, a difference in angle of ±10% or smaller is allowable and the lines L1 and L5 are considered to be in parallel with the center line L1.

Consequently, the film deposition rate on the sensor 11 can be considered to be equivalent to the film deposition rate on the substrate 5. Even when the angular distribution of sputter particles emitted from the target 28 is changed, it is possible to maintain the relationship in which the film deposition rate on the sensor 11 can be considered to be equivalent to the film deposition rate on the substrate 5. Therefore, highly accurate control of the film thickness can be achieved.

In Embodiment 2, the substrate placement area 5a and the sensor placement area 11a are provided on the opposite side of the center line L1 of the particle emission area 28a. In other words, the substrate placement area 5a and the sensor placement area 11a are placed in the two areas divided by the center line L1 of the particle emission area 8a. This can dramatically improve the flexibility in design within a film deposition chamber 1 (see FIG. 1) as compared with the case where the sensor is provided in the substrate placement area or the equivalent area when viewed from the particle emission area such as on the side or on the back of the substrate.

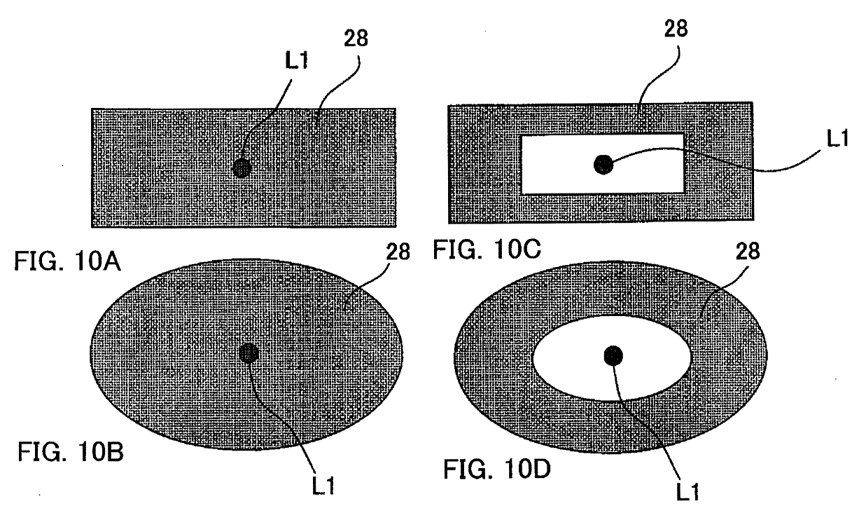

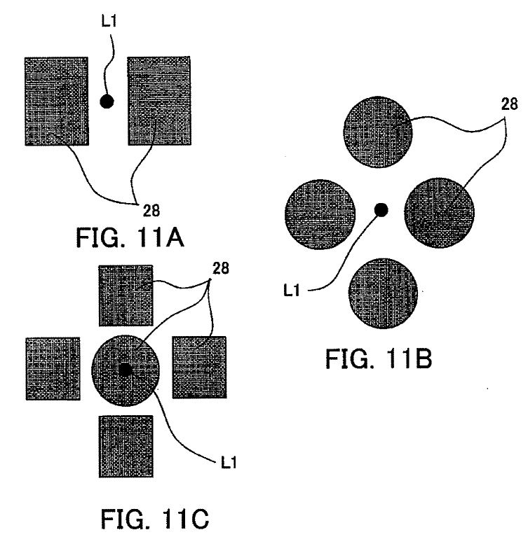

In the sputtering apparatus of Embodiment 2, it is possible to use targets 8 having various shapes and arrangements as shown in FIGS. 10A to 10D and 11A to 11C.

FIGS. 10A to 10D and 11A to 11C show the shapes of targets 28 in the horizontal direction when viewed from the center line L1. The target 28 can be formed in a rectangular shape and an oval shape as shown in FIGS. 10A and 10B, respectively, and a disk shape, not shown. As shown in FIGS. 10C and 10D, the targets 28 can be formed as a rectangular ring shape and an oval ring shape (or a circular shape), respectively, with a hole formed at the center.

As shown in FIGS. 11A to 11C, a plurality of targets 28 with the same or difference shapes may be placed on the same plane (plane orthogonal to the center line L1).

When any targets of the shapes and arrangements as shown are used, the center O and the center lines L1 of the particle emission area can be specified in accordance with the abovementioned definitions.

Embodiment 2 has been described in conjunction with the case where the center line L5 of the substrate placement area 5a (substrate 5) and the center line L11 of the sensor placement area 11a are in parallel with the center line L1 of the particle emission area 28a.

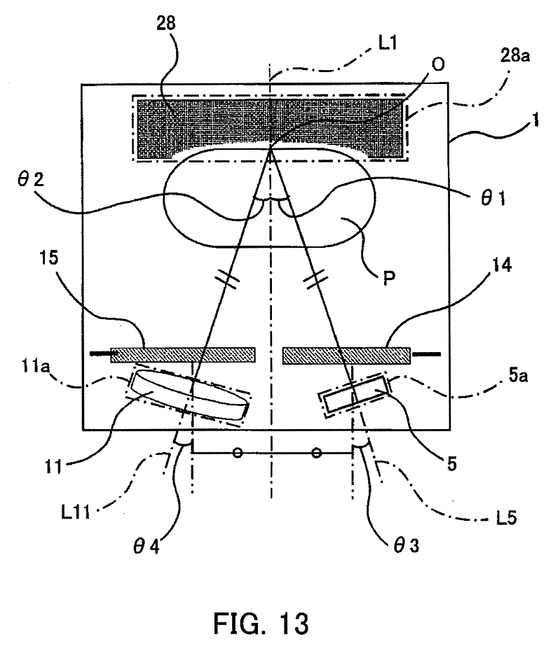

As shown in FIG. 13, however, it is possible to intentionally incline the center lines L5 and L11 by angles θ3 and θ4, respectively, toward the center line L1 of the particle emission area 28a to optimize the orientation of the substrate 5 and the sensor 11 with respect to the target 28. In this case, the angles θ3 and θ4 are desirably equal, and if a difference thereof is ±10% or smaller, the angles θ3 and θ4 are considered to be equivalent. The setting of the orientation described above may be performed in the other embodiments.

### Embodiment 3

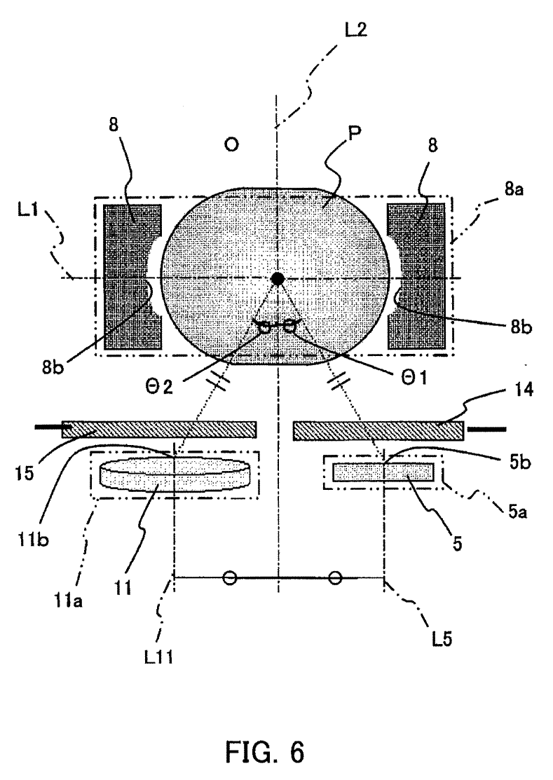

FIG. 6 shows the positional relationship between a particle emission area 8a, a substrate placement area 5a, and a sensor placement area 11a in the structure of a sputtering apparatus which is Embodiment 3 of the present invention. The three areas 5a, 8a, and 11a are shown by chain double dashed lines. FIG. 6 shows a substrate 5, targets 8, and a sensor 11 placed in the three areas 5a, 8a, and 11a, respectively.

The sputtering apparatus of Embodiment 3 is of the off-axis or opposed-target type in which the two planar targets 8 are placed such that their sputtering surfaces 8b are opposite to each other, similarly to Embodiment 1.

In FIG. 6, L1 and L2 represent a center line in the vertical direction and a center line in the horizontal direction, respectively, of the particle emission area 8a as described in Embodiment 1.

In the sputtering apparatus of Embodiment 3, the substrate placement area 5a (that is, the substrate 5) and the sensor placement area 11a (that is, the sensor 11) are placed in the positional relationship having symmetry with respect to the center line L2 of the particle emission area 8a. In other words, they are placed in the conjugate positional relationship from the viewpoint of film deposition conditions.

More specifically, the distance from the center O of the particle emission area 8a to the center 5b of the substrate placement area 5a (substrate 5) is equal to the distance from the center O of the particle emission area 8a to the center 11b of the sensor placement area 11a (sensor 11). The straight line connecting the center O of the particle emission area 8a to the center 5b of the substrate placement area 5a is referred to as a first straight line, while the straight line connecting the center O of the particle emission area 8a to the center 11b of the sensor placement area 11a is referred to as a second straight line.

In this case, an angle θ1 between the first straight line and the center line L1 is equal to an angle θ2 between the second straight line and the center line L2.

Similarly to Embodiment 2, when a difference between the distances or the angles is ±10% or less, the distances or the angles are considered to be equivalent.

Center lines L5 and L11 passing through the centers 5b and 11b of the substrate placement area 5a (substrate 5) and the sensor placement area 11a (sensor 11), respectively, are in parallel with the center line L2. An error of ±10% is also allowable for these parallel lines as in Embodiment 2.

Thus, the film deposition rate on the sensor 11 can be considered to be equivalent to the film deposition rate on the substrate 5. Even when the angular distribution of sputter particles emitted from the targets 8 is changed, it is possible to maintain the relationship in which the film deposition rate on the sensor 11 can be considered to be equivalent to the film deposition rate on the substrate 5. Therefore, highly accurate control of the film thickness can be achieved.

In Embodiment 3, similarly to Embodiment 2, the substrate placement area 5a and the sensor placement area 11a are placed in the two areas divided by the center line L2 of the particle emission area 8a. This can dramatically improve the flexibility in design within a film deposition chamber 1 (see FIG. 1).

In the sputtering apparatus of Embodiment 3, it is possible to use the targets 8 having various shapes and arrangements as shown in FIGS. 9A to 9E.

### Embodiment 4

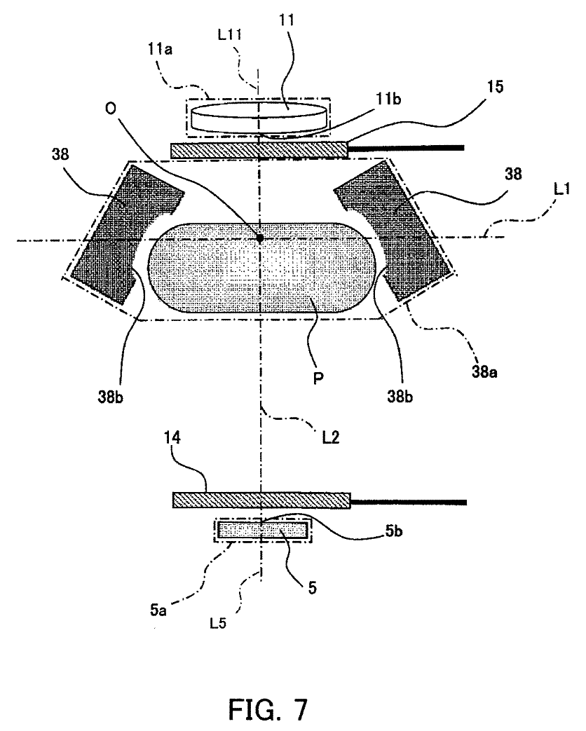

FIG. 7 shows the positional relationship between a particle emission area 38a, a substrate placement area 5a, and a sensor placement area 11a in the structure of a sputtering apparatus which is Embodiment 4 of the present invention. The three areas 5a, 38a, and 11a are shown by chain double dashed lines. FIG. 7 shows a substrate 5, targets 38, and a sensor 11 placed in the three areas 5a, 38a, and 11a, respectively.

The sputtering apparatus of Embodiment 4 is of the off-axis or opposed-target type as in Embodiment 1, in which the substrate placement area 5a and the sensor placement area 11a are placed on the opposite sides of the particle emission area 38a. However, in Embodiment 4, the two planar targets 38 are placed such that their sputtering surfaces 38b are opposite to each other and are inclined by 30 degrees or smaller with respect to a center line L2 of the particle emission area 38a in the horizontal direction. L5 and L11 passing through centers 5b and 11b of the substrate placement area 5a (substrate 5) and the sensor placement area 11a (sensor 11), respectively, are identical to the center line L2.

L1 represents the center line of the particle emission area 38a in the vertical direction described in Embodiment 1. In Embodiment 4, the targets 38 are inclined toward the substrate, but the center lines L1 and L2 are defined in the same manner as in Embodiment 1.

In Embodiment 4, similarly to Embodiment 1, the substrate placement area 5a and the sensor placement area 11a are placed in the two areas divided by the particle emission area 38a. This can dramatically improve the flexibility in design within a film deposition chamber 1 (see FIG. 1).

In Embodiment 4, the distance from the center O of the particle emission area 38a to the center 11b of the sensor placement area 11a is shorter than the distance from the center O of the particle emission area 38a to the center 5b of the substrate placement area 5a. In other words, the substrate placement area 5a and the sensor placement area 11a are not placed in the positional relationship having symmetry with respect to the center line L1 of the particle emission area 38a.

In this case, however, highly accurate control of the film thickness can be performed similarly to Embodiments 1 to 3 by setting film deposition conditions such that the film deposition rate on the sensor 11 is equivalent to the film deposition rate on the substrate 5 when the two planar targets 38 are inclined toward the substrate 5.

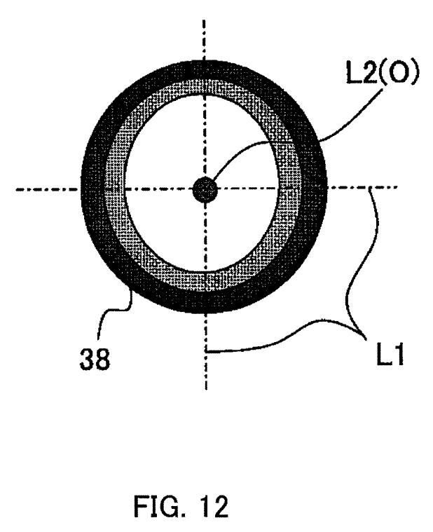

In the sputtering apparatus of Embodiment 4, the targets shown in FIGS. 9A, 9C to 9E can be used. In addition, as shown in FIG. 12, a ring-shaped (conical shape) target may be used. FIG. 12 shows the shape of the target 8 when viewed from the center line L2 in the horizontal direction.

While Embodiments 1 to 3 have been described above in conjunction with the difference of ±10% or less in the distance between the centers of the three areas or the difference of ±10% or less of the angle θ2 from the angle θ1. However, even when such a difference is slightly larger than ±10% (for example, ±15%), the positional relationship of the three areas may be considered to have symmetry if the positional relationship can be regarded as being conjugate from the viewpoint of film deposition conditions.

As described above, according to Embodiments 1 to 4, the films are deposited on the sensor located in the sensor placement area and on the substrate located in the substrate placement area under the same conditions. This can reduce or virtually eliminate the difference between the film deposition rate on the sensor and the film deposition rate on the substrate, so that the accuracy of film-thickness control can be improved. In addition, since the substrate placement area and the sensor placement area are divided by the center line of the particle emission area or the particle emission area, the flexibility in design can be enhanced.

Furthermore, the present invention is not limited to these preferred embodiments and various variations and modifications may be made without departing from the scope of the present invention.

This application claims foreign priority benefits based on Japanese Patent Application No. 2006-117850, filed on Apr. 21, 2006, which is hereby incorporated by reference herein in its entirety as if fully set forth herein.

What is claimed is:

1. A sputtering apparatus comprising:
a substrate placement area in which a substrate is placed;
a particle emission area in which a target is placed and sputter particles from the target are emitted; and
a sensor placement area in which a sensor is placed for measuring a thickness of a film formed on the substrate,
wherein the substrate placement area and the sensor placement area are provided in a positional relationship having symmetry with respect to a center line of the particle emission area.

2. The sputtering apparatus according to claim 1, wherein the substrate placement area and the sensor placement area are arranged on the opposite sides of the particle emission area, and
the positional relationship having symmetry is a positional relationship in which a distance from the center of the particle emission area to the center of the sensor placement area is different from a distance from the center of the particle emission area to the center of the substrate placement area by ±10% or smaller.

3. The sputtering apparatus according to claim 2, wherein the positional relationship having symmetry is a positional relationship in which an angle between a center line of the sensor placement area and the center line of the particle emission area is different from an angle between a center line of the substrate placement area and the center line of the particle emission area by ±10% or smaller.

4. The sputtering apparatus according to claim 1, wherein the substrate placement area and the sensor placement area are arranged on the opposite sides of the center line of the particle emission area, and
the positional relationship having symmetry is a positional relationship in which a distance from the center of the particle emission area to the center of the sensor placement area is different from the center of the particle emission area to the center of the substrate placement area by ±10% or smaller, and an angle between a straight line connecting the center of the particle emission area to the center of the sensor placement area and the center line of the particle emission area is different from an angle between a straight line connecting the center of the particle emission area to the center or the substrate placement area and the center line of the particle emission area by ±10% or smaller.

5. The sputtering apparatus according to claim 4, wherein the positional relationship having symmetry is a positional relationship in which an angle between a center line of the sensor placement area and the center line of the particle emission area is different from an angle between a center line of the substrate placement area and the center line of the particle emission area by ±10% or smaller.

6. The sputtering apparatus according to claim 1, wherein a plurality of the targets which are opposite to each other or the target in a ring shape is placed in the particle emission area.

7. The sputtering apparatus according to claim 1, wherein the target is placed in the particle emission area such that a surface of the target to be sputtered faces the substrate placement area.

8. A sputtering apparatus, comprising:
a substrate placement area in which a substrate is placed;
a particle emission area in which a target is placed and sputter particles from the target are emitted; and
a sensor placement area in which a sensor is placed for measuring a thickness of a film formed on the substrate,
wherein the substrate placement area and the sensor placement area are provided on the opposite sides with respect to the particle emission area.

9. The sputtering apparatus according to claim 8, wherein a distance from the center of the particle emission area to the center of the sensor placement area is different from a distance from the center of the particle emission area to the center of the substrate placement area by ±10% or smaller.

10. The sputtering apparatus according to claim 8, wherein a plurality of the targets which are opposite to each other or the target in a ring shape is placed in the particle emission area.
